(19) United States
(12) Patent Application Publication
(10) Pub. No.: US 2026/0371970 A1
(43) Pub. Date: Nov. 19, 2026

(54) SEMICONDUCTOR DIE AND METHODS OF FORMATION

(71) Applicant: Taiwan Semiconductor Manufacturing Company, Ltd., Hsinchu (TW)

(72) Inventors: I-Chun WANG, Hsinchu (TW); Ching-Sheng CHU, Hsinchu (TW); Chern-Yow HSU, Hsinchu (TW); Yi-Fong LAI, Hsinchu (TW); Wei-Dung TSAI, Hsinchu (TW); Kong-Beng THEI, Hsinchu (TW); Jung-Hui KAO, Hsinchu (TW); Jing-Jung HUANG, Hsinchu (TW)

(21) Appl. No.: 19/751,911

(22) Filed: Jul. 23, 2026

Related U.S. Application Data
(62) Division of application No. 18/400,440, filed on Dec. 29, 2023.

(51) Int. Cl. H10P 50/00; H10P 72/30; H10P 74/00; H10P 76/20; H10W 20/00; H10W 72/30; H10W 72/90

(52) U.S. Cl. CPC H10P 50/71; H10P 72/3302; H10P 74/273; H10P 76/2041; H10W 20/043; H10W 72/321; H10W 72/342; H10W 72/921; H10W 72/923; H10W 72/941

(57) ABSTRACT

Some implementations herein include a semiconductor die and methods of formation. The semiconductor die includes an array of interconnect pad structures, including interconnect pad structures having surfaces located within an overlay region of an active device area of the semiconductor die. As part of manufacturing the semiconductor die, temporary conductive structures are formed across the overlay region to support wafer acceptance testing and/or circuit probe testing process. Forming the temporary conductive structures includes using an anti-reflective coating layer having a composition that enables the temporary conductive structures to be formed using a single etch cycle. Relative to other semiconductor dies manufactured using temporary conductive structures formed using an anti-reflective coating layer having another composition (and that may require multiple etch cycles), the semiconductor die includes a reduced difference in step heights between interconnect pad structures in the overlay region and other regions of the active device area.

### RELATED APPLICATION

This application is a divisional of U.S. Patent Application No. 18/400,440, filed Dec. 29, 2023, which is incorporated herein by reference in its entirety.

### BACKGROUND

A semiconductor die may be subjected to circuit probe (CP) testing and/or a wafer acceptance testing (WAT) to verify one or more performance parameters of the semiconductor die, to verify one or more design parameters of the semiconductor die, and/or to determine one or more other parameters associated with the semiconductor die.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A and 2B are diagrams of an example semiconductor die described herein.

FIGS. 3A and 3B are diagrams of an example implementation described herein.

FIGS. 4A-4C and 5A-5H are diagrams of semiconductor processing operations related to forming a semiconductor die described herein.

FIG. 6 is a diagram of an example semiconductor die described herein.

FIG. 7 is a diagram of example components of a device described herein.

FIGS. 8 and 9 are diagrams of example processes described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A semiconductor die may be subjected to circuit probe (CP) testing and/or a wafer acceptance testing (WAT) to verify one or more performance parameters of the semiconductor die, to verify one or more design parameters of the semiconductor die, and/or to determine one or more other parameters associated with the semiconductor die. The CP testing and/or WAT testing may use test pads around a periphery of the semiconductor die that route and connect to integrated circuits and/or test structures within an active device area of the semiconductor die using temporary conductive structures.

In some cases, the temporary conductive structures route across regions (e.g., “overlay regions”) of a passivation layer within the active device area over which interconnect pad structures may be subsequently formed. During formation of the temporary conductive structures, and for patterning purposes, a layer of an anti-reflective coating material may be on and/or over a layer of a conductive material that is used to form the conductive structures. Forming the temporary conductive structures may include two etch cycles, including a first etch cycle to etch a pattern from the layer of the conductive material followed by a second etch cycle to remove the layer of the anti-reflective material. Each etch cycle may remove a respective portion of the passivation layer.

After removal of the temporary conductive structures, interconnect pad structures may be formed in the overlay region and other regions of the active device area. However, relative to interconnect pad structures within the other regions of the active device area, interconnects pads within the overlay region may include a different step height (e.g., upper surface height) having a magnitude that is based on the two etch cycles.

Differences in step heights above a threshold may reduce a capability of a pick-and-place tool to obtain a secure hold of the semiconductor die due to low contact force between the pick-and-place tool and the interconnect pad structures. This can result in an inability of the pick-and-place tool to pick up the semiconductor die and/or can result in the pick-and-place tool dropping the semiconductor die, which can damage the semiconductor die and cause the semiconductor die to be nonoperational.

Some implementations herein include a semiconductor die and methods of formation. The semiconductor die includes an array of interconnect pad structures, including interconnect pad structures having surfaces located within an overlay region of an active device area of the semiconductor die. As part of manufacturing the semiconductor die, temporary conductive structures are formed across the overlay region to support a WAT testing and/or CP testing process. Forming the temporary conductive structures includes using an anti-reflective coating layer having a composition that enables the temporary conductive structures to be formed using a single etch cycle. Relative to other semiconductor dies manufactured using temporary conductive structures formed using an anti-reflective coating layer having another composition (and that may require multiple etch cycles), the semiconductor die includes a reduced difference in step heights between interconnect pad structures in the overlay region and other regions of the active device area.

In this way, a magnitude and a uniformity of a contact force between a pick-and-place tool and the semiconductor die is maintained to enable a repeatable and reliable pick-and-place operation. This increases the productivity of the pick-and-place tool (the pick-and-place tool can spend less time attempting to securely pick up and move the semiconductor die, thereby processing a greater quantity of semiconductor dies) and/or reduces the likelihood of damage to the semiconductor die, among other examples.

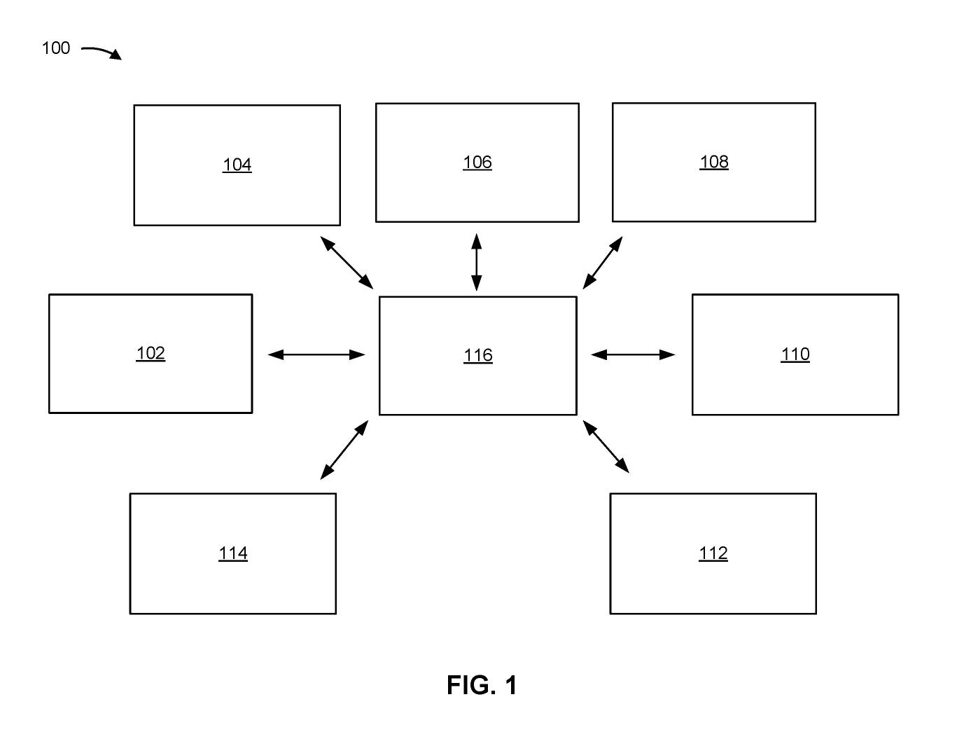

FIG. 1 is a diagram of an example environment 100 in which systems and/or methods described herein may be implemented. As shown in FIG. 1, the example environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, a wafer testing tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma enhanced CVD (PECVD) tool, a low-pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of different types of deposition tools 102. “Deposition tool 102,” as used herein, may refer to one or more deposition tools 102, one or more of the same type of deposition tools 102, and/or one or more different types of deposition tools 102, among other examples.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor die layer patterns for forming one or more semiconductor dies, may include a pattern for forming one or more structures of a semiconductor die, may include a pattern for etching various portions of a semiconductor die, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor die. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor die. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor die with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor die). The polishing pad and the semiconductor die may be pressed together by a dynamic polishing head and held in place by the retaining ring. The dynamic polishing head may rotate with different axes of rotation to remove material and even out any irregular topography of the semiconductor die, making the semiconductor die ﬂat or planar.

The plating tool 112 is a semiconductor processing tool that is capable of plating a substrate (e.g., a wafer, a semiconductor die, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The wafer testing tool 114 includes one or more tools that are capable of performing wafer-level testing of semiconductor dies formed on a semiconductor wafer. The wafer-level testing may include wafer acceptance tests (WATs), circuit probe (CP) tests, and/or other types of electrical tests that are performed prior to dicing the semiconductor wafer into individual semiconductor dies. Examples of the wafer testing tool include an automated test equipment (ATE) that is coupled with a wafer probing station. Examples of wafer-level tests include a parametric test, a continuity test, a resistance test, a current test, and/or a voltage test, among other examples.

Wafer/die transport tool 116 includes a mobile robot, a robot arm, a tram or rail car, an overhead hoist transport (OHT) system, an automated materially handling system (AMHS), a pick-and-place tool, and/or another type of device that is configured to transport substrates and/or semiconductor dies between semiconductor processing tools 102-112, that is configured to transport substrates and/or semiconductor dies between processing chambers of the same semiconductor processing tool, and/or that is configured to transport substrates and/or semiconductor dies to and from other locations such as a wafer rack, a storage room, and/or the like. In some implementations, a wafer/die transport tool 116 (e.g., a pick-and-place tool) is configured to place semiconductor dies on a semiconductor die package substrate. The semiconductor dies may be electrically coupled through redistribution layers in the semiconductor die package substrate. In some implementations, wafer/die transport tool 116 may be a programmed device that is configured to travel a particular path and/or may operate semi-autonomously or autonomously. In some implementations, the example environment 100 includes a plurality of wafer/die transport tools 116.

For example, the wafer/die transport tool 116 may be included in a cluster tool or another type of tool that includes a plurality of processing chambers, and may be configured to transport substrates and/or semiconductor dies between the plurality of processing chambers, to transport substrates and/or semiconductor dies between a processing chamber and a buffer area, to transport substrates and/or semiconductor dies between a processing chamber and an interface tool such as an equipment front end module (EFEM), and/or to transport substrates and/or semiconductor dies between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor die) and a plurality of types of deposition processing chambers (e.g., processing chambers for depositing different types of materials, processing chambers for performing different types of deposition operations). In these implementations, the wafer/die transport tool 116 is configured to transport substrates and/or semiconductor dies between the processing chambers of the deposition tool 102 without breaking or removing a vacuum (or an at least partial vacuum) between the processing chambers and/or between processing operations in the deposition tool 102, as described herein.

In some implementations, one or more of the semiconductor processing tools 102-114 may perform a series of semiconductor processing operations. For example, the series of semiconductor processing operations includes forming a integrated circuit device in an active device region of a semiconductor die. The series of semiconductor processing operations includes forming a dielectric layer over the integrated circuit device. The series of semiconductor processing operations includes forming, over the dielectric layer, a temporary conductive structure that includes a top anti-reflective coating layer and that connects the integrated circuit device with a test pad in a periphery region of the semiconductor die, where forming the temporary conductive structure includes using a single etch operation to remove portions of the top anti-reflective coating layer and portions of one or more conductive layers between the top anti-reflective coating layer and the dielectric layer. The series of semiconductor processing operations includes testing the integrated circuit device using the temporary conductive structure. The series of semiconductor processing operations includes removing the temporary conductive structure. The series of semiconductor processing operations includes forming an interconnect pad structure on the dielectric layer.

Additionally, or alternatively and in some implementations, the series of semiconductor processing operations includes forming an oxide layer. The series of semiconductor processing operations includes forming, over the oxide layer, a layer stack including an aluminum oxide layer on an aluminum layer that is on a tantalum nitride layer. The series of semiconductor processing operations includes forming, over the layer stack, a mask pattern that masks a portion of the layer stack. The series of semiconductor processing operations includes forming, from the layer stack, a temporary conductive structure using a single removal operation to remove unmasked portions of the layer stack.

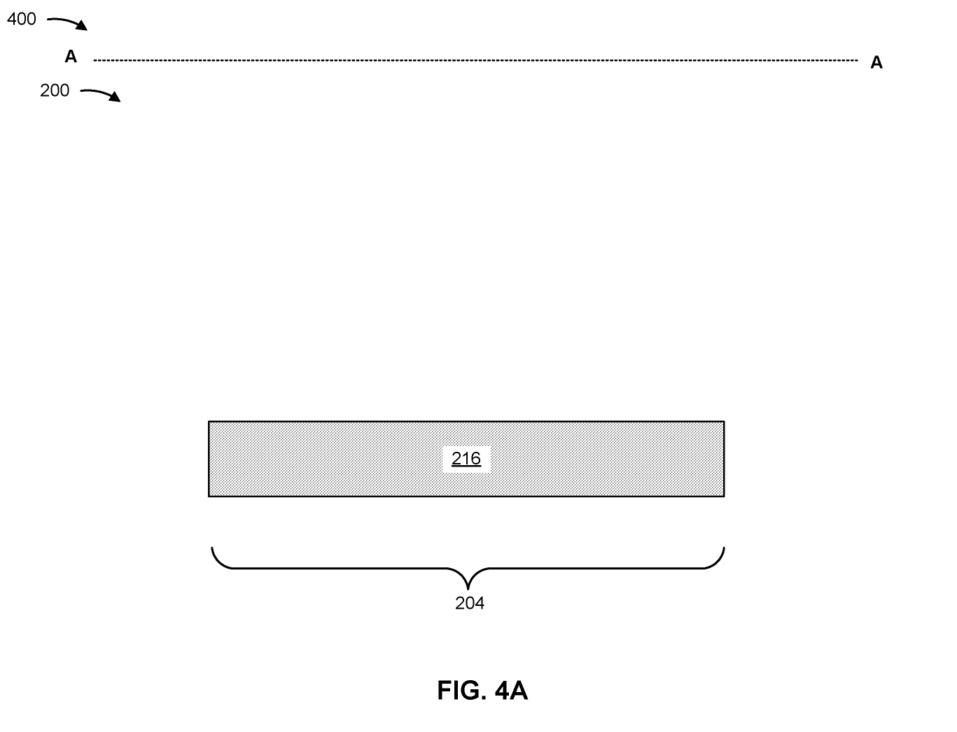

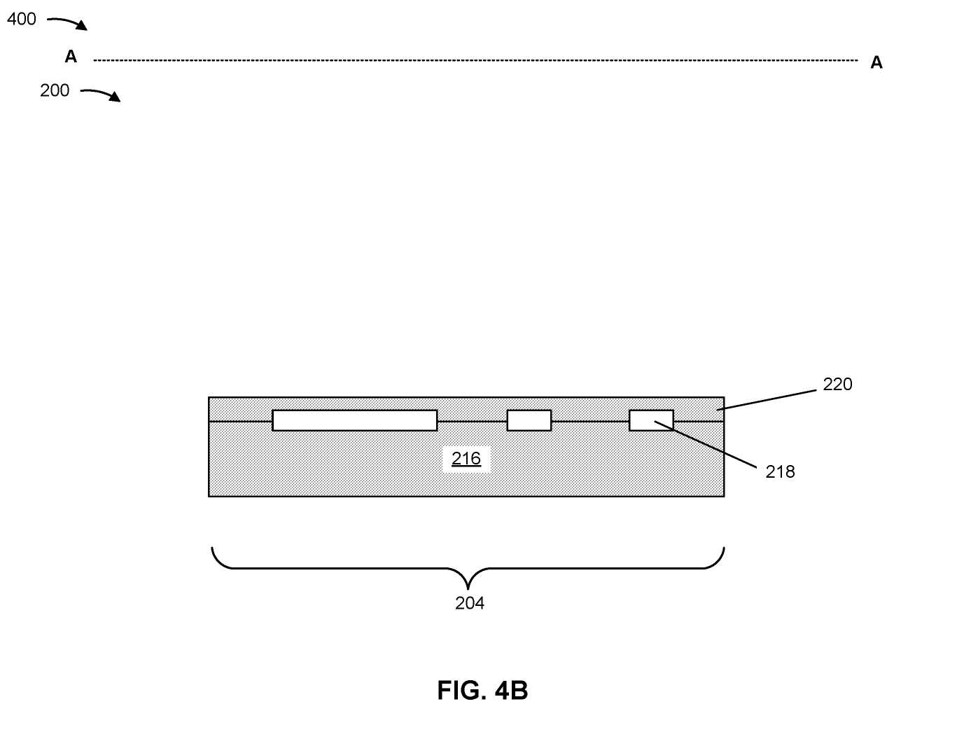

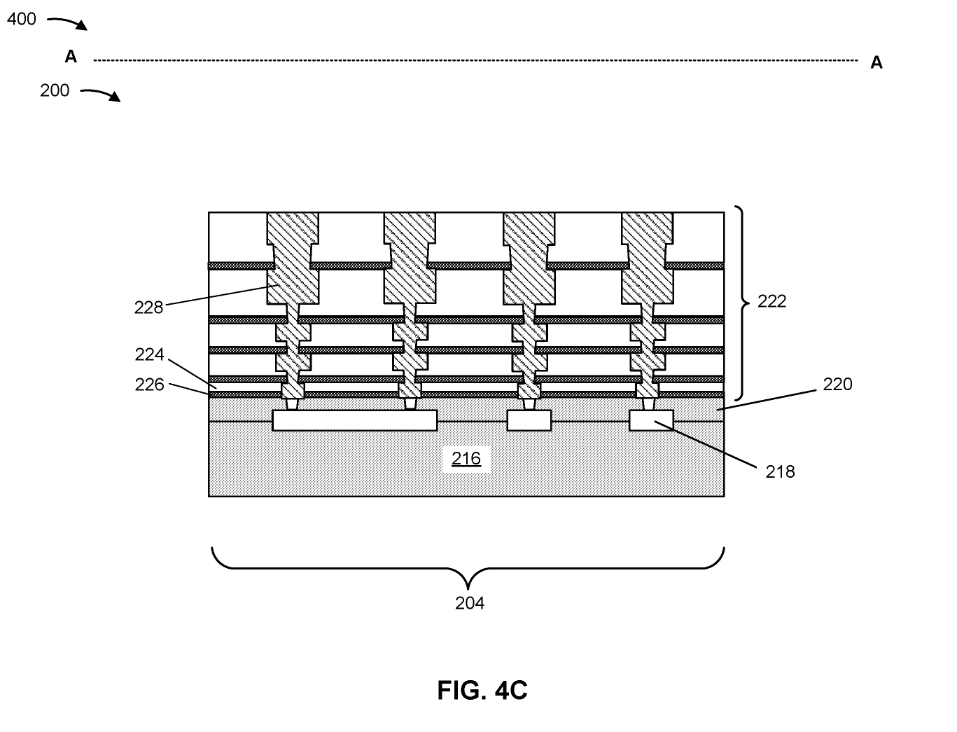

One or more of the semiconductor processing tools 102-114 may perform other semiconductor processing operations described herein, such as in connection with FIGS. 4A-4C, 5A-5H-8, and/or 9, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

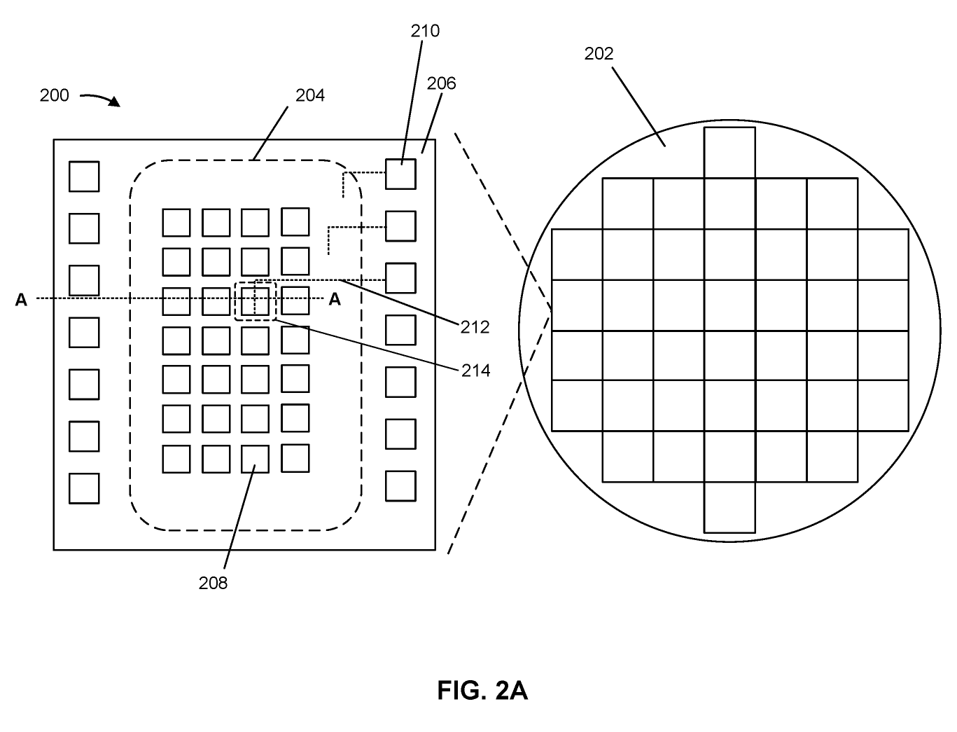

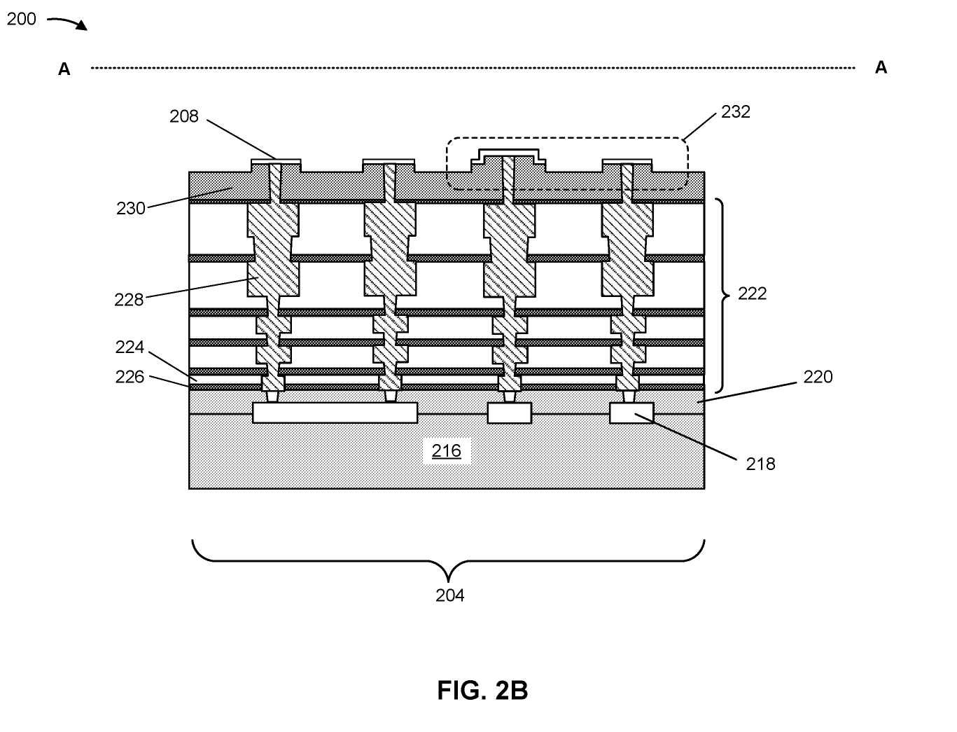

FIGS. 2A and 2B are diagrams of an example semiconductor die 200 described herein. One or more of the semiconductor processing tools 102-114 and/or the wafer/die transport tool 116 may be used to perform one or more semiconductor processing operations to form the semiconductor die 200. An example of the semiconductor die 200 includes a light emitting diode (LED) die that includes an integrated circuit device such a light emitting diode device, among other examples. Other examples of the semiconductor die 200 include a monolithic system on chip (SoC) die that includes a plurality of different functionalities, such as a central processing unit (CPU) die, a graphics processing unit (GPU) die, a digital signal processing (DSP) die, an application specific integrated circuit (ASIC) die, a memory die, and/or another type of SoC die.

In some implementations, the semiconductor die 200 is a “chiplet” that is combined with other chiplets in a semiconductor die package to form a component used in a system or application. For example, and in a case where the semiconductor die 200 is an LED chiplet (e.g., a micro LED or a mini LED). The semiconductor die 200 may be combined with other chiplets and/or other semiconductor dies (e.g. other LED chiplets) in the semiconductor package to form an LED component that is used in an automotive lighting application, a sign or billboard application, or a high resolution screen application, among other examples.

FIG. 2A illustrates a top view of a semiconductor die 200. As shown in FIG. 2A, the semiconductor die 200 is manufactured on a wafer 202 along with a plurality of other semiconductor dies. The semiconductor die 200 includes an active device region 204 and a periphery region 206 that surrounds the active device region 204 in the top view of the semiconductor die 200.

The active device region 204 includes interconnect pad structures 208 (e.g., LED bump pads) that enable electrical signals and/or power to be provided to and/or transferred from integrated circuitry included in the active device region 204. The interconnect pad structures 208 may include a conductive material such as aluminum (Al), copper, (Cu) aluminum copper (AlCu), tungsten (W), cobalt (Co), ruthenium (Ru), titanium (Ti), gold (Au) or another suitable conductive material.

The periphery region 206 provides a region around the perimeter of the semiconductor die 200 in which test pads 210 are formed to enable wafer-level testing of the semiconductor die 200 prior to the semiconductor die 200 being diced from the wafer 202. The test pads 210 may include a conductive material such aluminum (Al), copper, (Cu) aluminum copper (AlCu), tungsten (W), cobalt (Co), ruthenium (Ru), titanium (Ti), gold (Au) or another suitable conductive material. In some implementations, the periphery region 206 (including the test pads 210) is included in a scribe area of the wafer 202. In such a case, the periphery region 206 may be excised (e.g., diced, sawn) from the semiconductor die 200 prior to incorporating the semiconductor die 200 in the semiconductor die package.

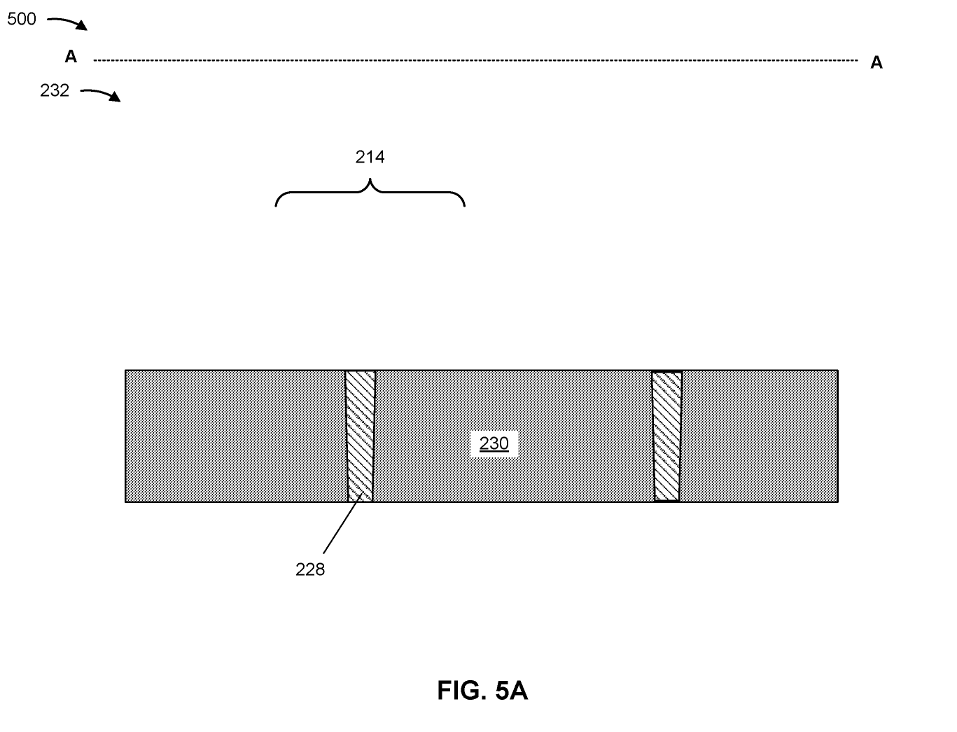

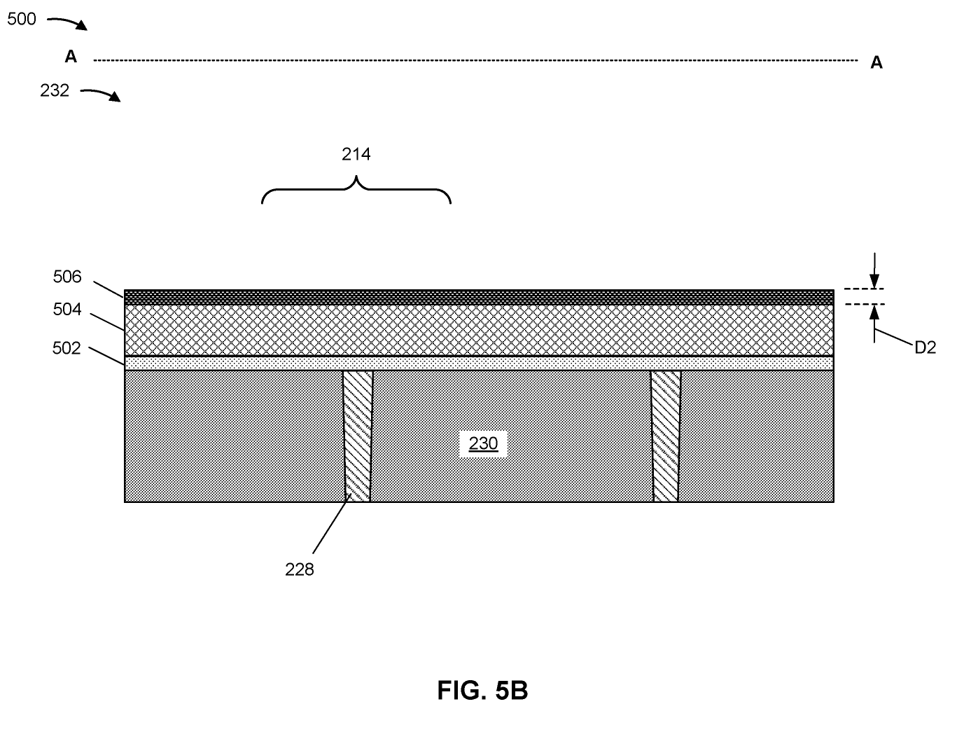

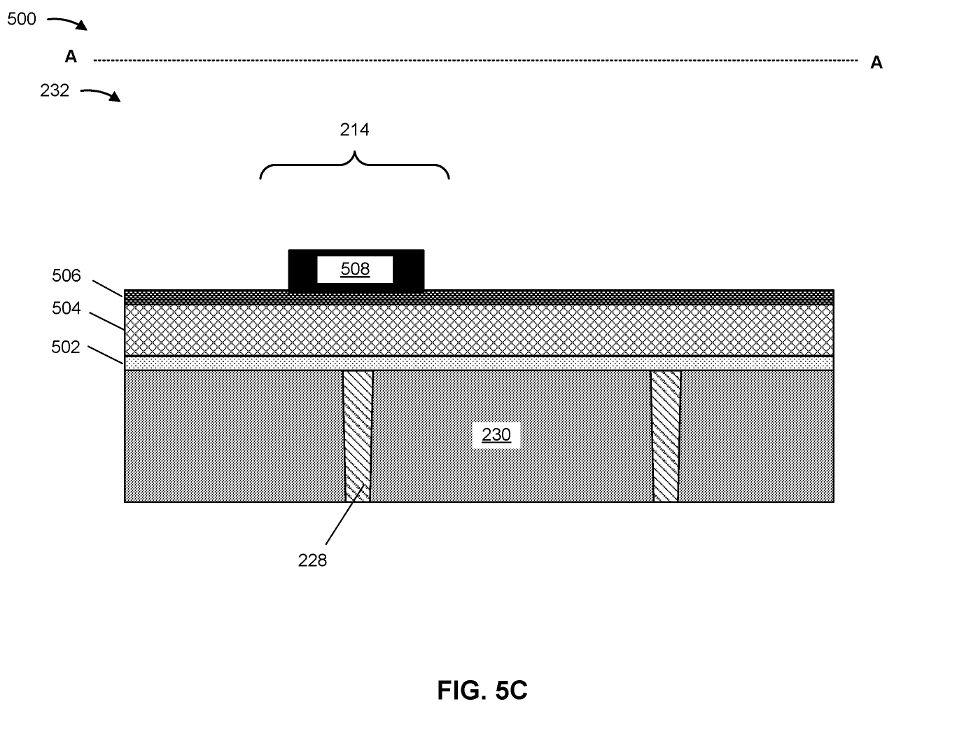

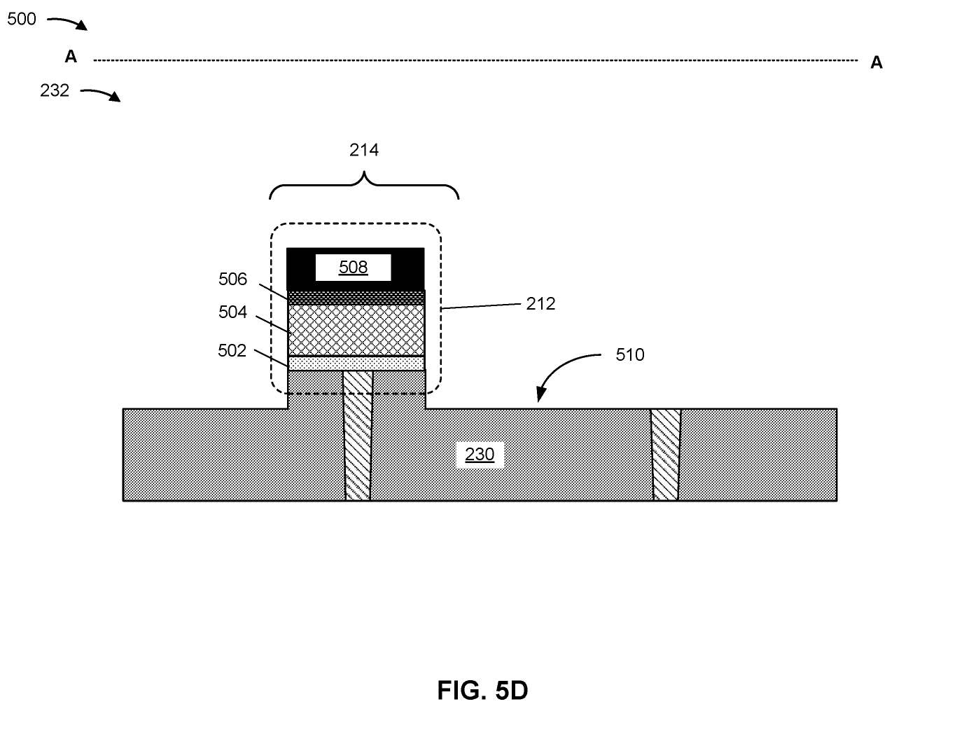

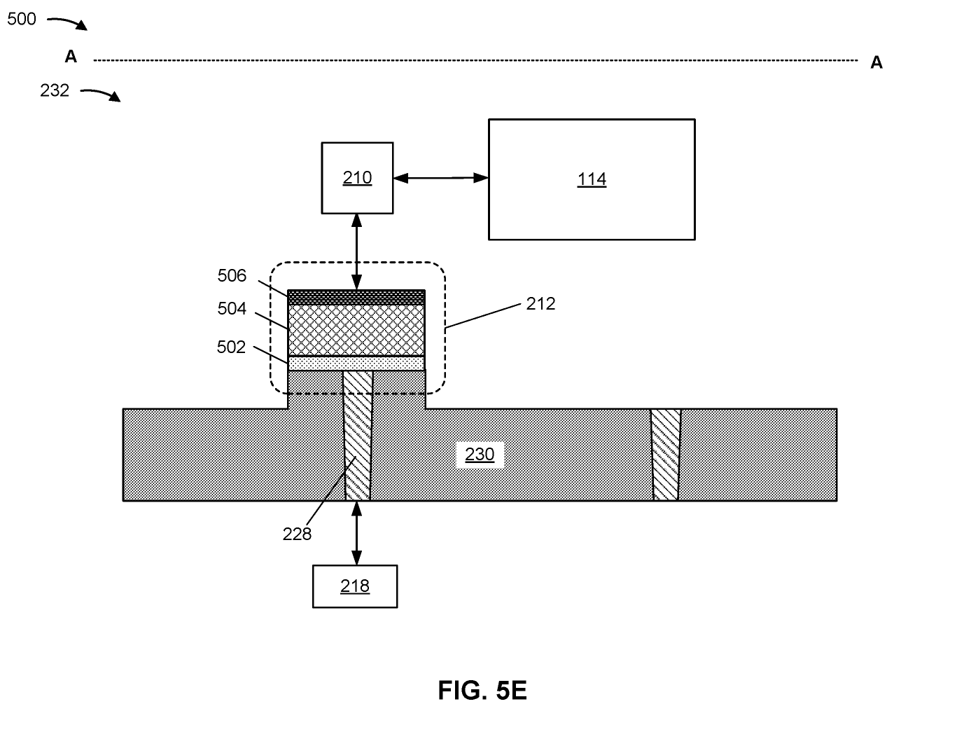

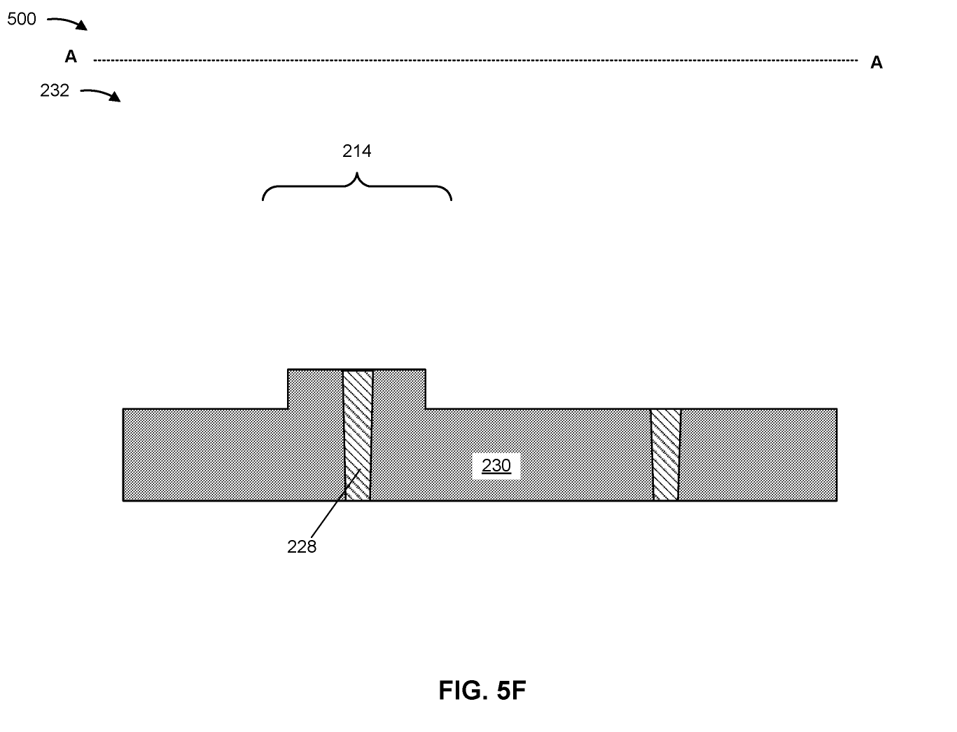

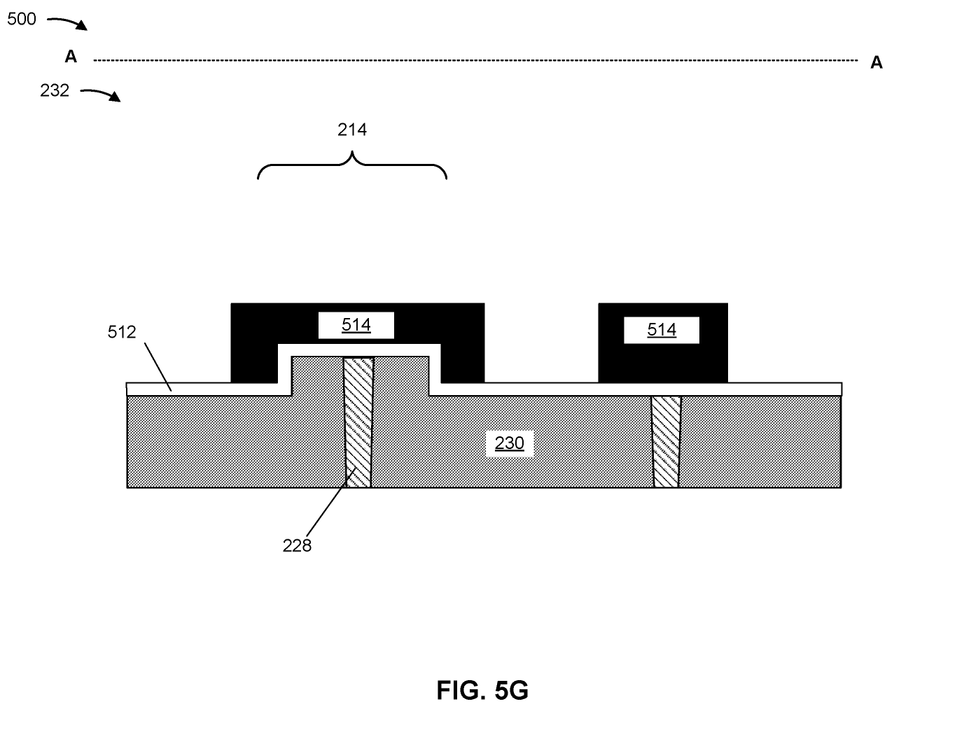

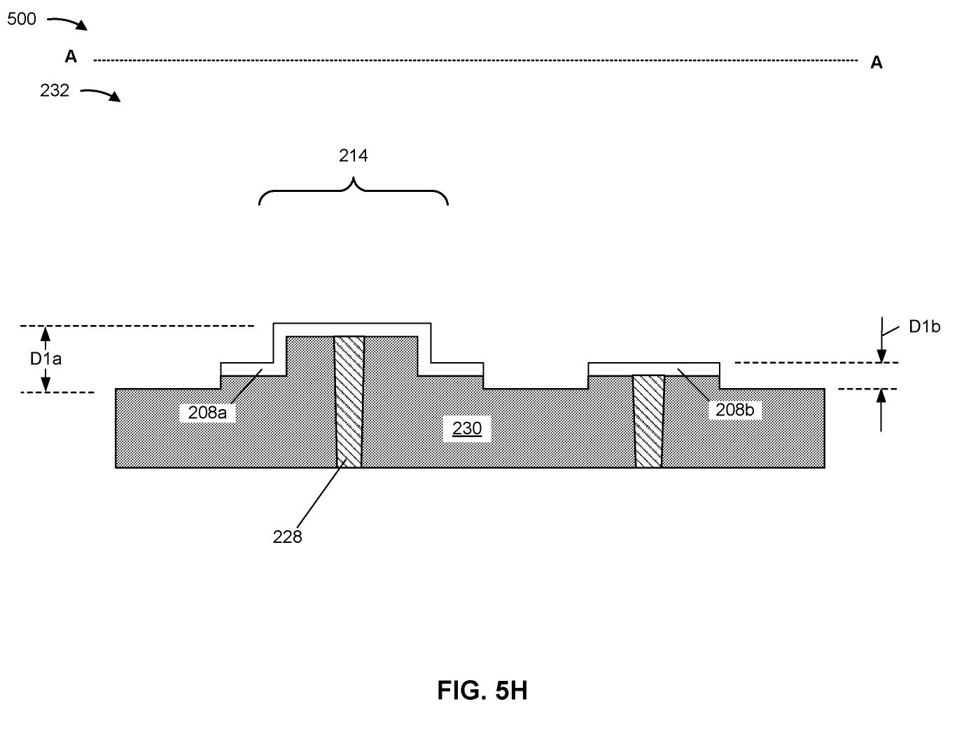

For testing purposes (e.g., CP or WAT testing at intermediate manufacturing stages of the semiconductor die 200), temporary conductive structures 212 (e.g., wires) may be formed between the test pads 210 and integrated circuit devices within the active device region 204. In some implementations, the temporary conductive structures 212 include a multi-layer stack of materials including aluminum oxide (AlOₓ) on aluminum (Al) on tantalum nitride (TaN). In some implementations, formation of the temporary conductive structures 212 includes forming the temporary conductive structures 212 in one or more overlay region (s) 214 (e.g., regions of the active device region 204 that are shared by one or more of the temporary conductive structures 212 and one or more of the interconnect pad structures 208). As described in greater detail in connection with FIGS. 5A-5H, formation of the temporary conductive structures 212, which occurs prior to formation the interconnect pad structures 208, may cause step heights (e.g., step heights of the interconnect pad structures 208) in the one or more overlay regions 214 to be greater relative to other regions of the semiconductor die 200.

FIG. 2B illustrates a cross-sectional view of the active device region 204 along line A-A in FIG. 2A. As shown in FIG. 2B, the semiconductor die 200 includes a substrate 216. The substrate 216 corresponds to a portion of the wafer 202 on which the semiconductor die 200 is formed. The substrate 216 may correspond to a sapphire substrate, a silicon carbide substrate, a silicon substrate, a gallium nitride-on-sapphire substrate, or a gallium nitride-on-silicon substrate, among other examples.

Integrated circuit device(s) 218 are included in and/or on the substrate 216 in the active device region 204 of the semiconductor die 200. The IC device(s) 218 include light emitting diodes, transistors pixel sensors, capacitors, resistors, inductors, photodetectors, transceivers, transmitters, receives, optical circuits, and/or other types of semiconductor dies.

A dielectric layer 220 is included on and/or over the substrate 216. The dielectric layer 220 includes dielectric material(s) that enable various portions of the substrate 216 and/or the IC device(s) 218 to be selectively etched or protected from etching, and/or to electrically isolate the IC device(s) 218. The dielectric layer 220 includes a silicon nitride (SiₓN_{y}), an oxide (e.g., a silicon oxide (SiOₓ) and/or another oxide material), and/or another type of dielectric material.

An interconnect region 222 may be included above the substrate 216 and above the IC device(s) 218. In some implementations, and as shown in FIG. 2B, the interconnect region 222 includes a plurality of dielectric layers that are arranged in a direction that is approximately perpendicular to the substrate 216. The dielectric layers may include interlayer dielectric layers (ILDs) 22, etch stop layers (ESLs) 226, and/or another type of dielectric layer. The ILDs 224 and the ESLs 226 may be vertically-arranged and interspersed in an alternating manner. The ILDs 224 and the ESLs 226 each include a silicon nitride (SiₓN_{y}), an oxide (e.g., a silicon oxide (SiOₓ) and/or another oxide material), and/or another type of dielectric material. In some implementations, one or more of the ILDs 224 and ESLs 226 include dielectric materials to provide etch selectivity to enable various structures to be formed in the interconnect region 222.

The interconnect region 222 may include one or more metallization layers 228. The metallization layers 228 are electrically coupled and/or physically coupled with one or more of the IC device(s) 218. The metallization layers 228 correspond to circuitry that enables signals and/or power to be provided to and/or from the IC device(s) 218.

The metallization layers 228 include vias, trenches, contacts, plugs, interconnects, and/or other types of conductive structures. The metallization layers 228 include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

A top dielectric layer 230 is included above in the semiconductor die 200 above the substrate 216. The top dielectric layer 230 may be included for passivation of the interconnect region 222 and/or of the IC device(s) 218 included in the active device region 204. The top dielectric layer 230 includes a silicon nitride (SiₓN_{y}), an oxide (e.g., a silicon oxide (SiOₓ) and/or another oxide material), and/or another type of dielectric material.

The interconnect pad structures 208 are included over and/or on the top dielectric layer 230. The interconnect pad structures 208 may connect with the IC device(s) 218 through the metallization layers 228. The interconnect pad structures 208 may include aluminum (Al), aluminum copper (AlCu), tungsten (W), cobalt (Co), ruthenium (Ru), titanium (Ti), gold (Au), and/or another conductive material.

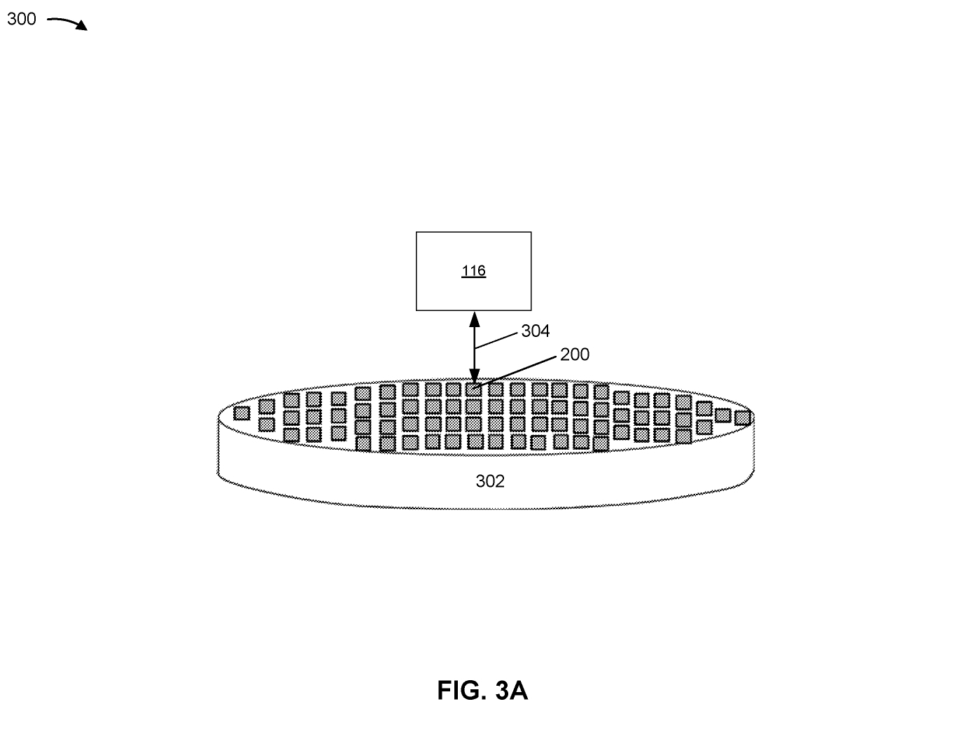

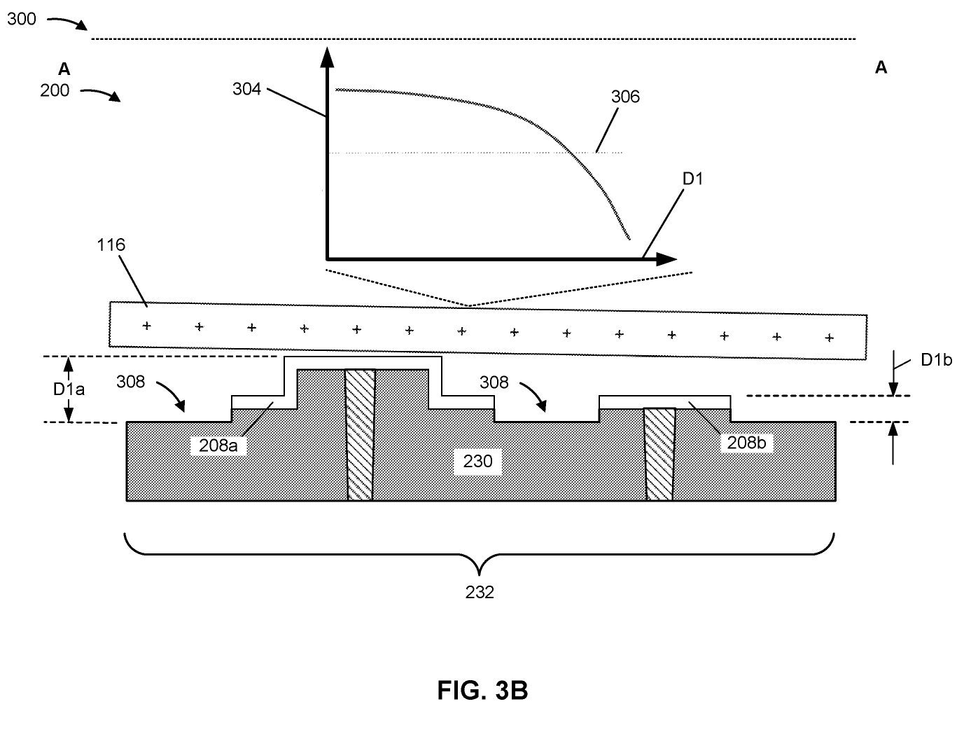

As described in greater detail in connection with FIG. 3, and based on manufacturing techniques described in connection with FIGS. 5A-5H, a variation in step heights across the interconnect pad structures 208 may reduce a capability of a pick-and-place tool to obtain a secure hold of the semiconductor die 200 due to low contact force between the pick-and-place tool and the interconnect pad structures 208. This can result in an inability of the pick-and-place tool to pick up the semiconductor die 200 and/or can result in the pick-and-place tool dropping the semiconductor die 200, which can damage the semiconductor die 200 and cause the semiconductor die 200 to be nonoperational. In FIGS. 3 and 5A-5H, interconnect pad region 232 is used to describe additional details related to such a variation in step heights.

As indicated above, FIGS. 2A and 2B are provided as an example. Other examples may differ from what is described with regards to FIGS. 2A and 2B.

FIGS. 3A and 3B are diagrams of an example implementation 300 described herein. The implementation 300 includes a pick-and-place operation using a semiconductor processing tool having pick-and-place functionality (e.g., the wafer/die transport tool 116).

As shown in FIG. 3A, a carrier 302 (a substrate or a film frame structure, among other examples) is populated with a plurality of the semiconductor die(s) 200 (e.g., chiplets). In FIG. 3A, the wafer die/transport tool 116 may remove the semiconductor die 200 from the carrier 302 as part of a pick-and-place operation that transfers the semiconductor die 200 from a first semiconductor processing operation to a second semiconductor processing operation. As an example, the wafer-die transport tool 116 may perform a pick-and-place operation that transfers the semiconductor die 200 from a dicing operation that dices or saws the semiconductor die 200 from a substrate (e.g., a wafer) to a packaging operation that integrates the semiconductor die 200 into a semiconductor die package. As part of the pick-and-place operation, a component such as an electric and/or magnetically biased pick-and-place head may use a normalized force 304 to extract the semiconductor die 200 from the carrier 302.

Turning to FIG. 3B, and as shown with reference to the interconnect pad region 232, the wafer/die transport tool 116 may be used to pick up the semiconductor die 200 (e.g., extract the semiconductor die 200 from the carrier 302). The wafer/die transport tool 116 may be biased with a positive electrical or magnetic bias, and the interconnect pad structures 208a and/or 208b may be biased with a negative electrical or magnetic bias (e.g., because of the metal material(s) of the interconnect pad structures 208a and 208b). The electric and/or magnetic force between the wafer/die transport tool 116 and the interconnect pad structures 208a and 208b causes an attraction force to secure the semiconductor die 200 against the wafer/die transport tool 116. The positive electrical or magnetic bias may be removed from the wafer/die transport tool 116 to release the electric and/or magnetic force on the semiconductor die 200 so that the semiconductor die 200 may be placed on a semiconductor package substrate, on a printed circuit board, and/or on another surface.

As further shown in FIG. 3B, a threshold 306 for the normalized force 304 between the wafer/die transport tool 116 and the interconnect pad structures 208a and 208b may be used to determine whether the wafer/die transport tool 116 can apply a sufficient amount of electric and/or magnetic force to the interconnect pad structures 208a and 208b to successfully pick up the semiconductor die 200. In FIG. 3B, and as described in greater detail in connection with FIGS. 5A-5H, a step height D1a may correspond to a distance from surface(s) 308 formed in the top dielectric layer 230 to a top of the interconnect pad structure 208a. Furthermore, a step height D1b may correspond to a distance from the surface(s) 308 to a top of the interconnect pad structure 208b. If a difference in the step heights D1a and D1b is too great, an angle of the wafer/die transport tool 116 may be too steep, which reduces the contact surface area between the wafer/die transport tool 116 and the interconnect pad structures 208a and 208b, reduces the normalized force 304 to not satisfy the threshold 306, and prevents the wafer/die transport tool 116 from applying a sufficient amount of electric and/or magnetic force to the interconnect pad structures 208a and 208b.

By applying the sufficient amount of electric and/or magnetic force to the interconnect pad structures 208a and 208b (and across other interconnect pad structures of the semiconductor die 200), a magnitude and a uniformity of a contact force between the wafer/die transport tool 116 and the semiconductor die 200 is maintained to enable a repeatable and reliable pick-and-place operation. This increases the productivity of the wafer/die transport tool 116 and/or reduces the likelihood of damage to the semiconductor die 200, among other examples.

As indicated above, FIGS. 3A and 3B are provided as an example. Other examples may differ from what is described with regard to FIGS. 3A and 3B.

FIGS. 4A-4C are diagrams of example semiconductor processing operations 400 related to forming a semiconductor die described herein (e.g., the semiconductor die 200). The semiconductor processing operations 400 include IC devices (e.g., the IC device(s) 218) and an interconnect region (e.g., the interconnect region 222) of the semiconductor die. One or more of the semiconductor processing tools 102-114 and/or the wafer/die transport tool 116 may be used to perform one or more of the semiconductor processing operations 400 described in connection with FIGS. 4A-4C. In some implementations, one or more of the semiconductor processing operations described in connection with FIGS. 4A-4C may be performed using another semiconductor processing tool.

Turning to FIG. 4A, the substrate 216 may be provided. The substrate 216 may be provided in the form of a semiconductor wafer such as a silicon (Si) wafer. The semiconductor die 200 may be formed on the substrate 216 along with a plurality of other semiconductor dies 200.

As shown in FIG. 4B, the IC device(s) 218 may be formed in and/or on the substrate 216 in the active device region 204 of the semiconductor die 200. One or more of the semiconductor processing tools 102-114 may be used to form one or more portions of the IC device(s) 218. For example, a deposition tool 102 may be used to perform various deposition operations to deposit layers of the IC device(s) 218, and/or to deposit photoresist layers for etching the substrate 216 and/or portions of the deposited layers. As another example, an exposure tool 104 may be used to expose the photoresist layers to form patterns in the photoresist layers. As another example, a developer tool 106 may develop the patterns in the photoresist layers. As another example, an etch tool 108 may be used to etch the substrate 216 and/or portions of the deposited layers to form the IC device(s) 218. As another example, a planarization tool 110 may be used to planarize portions of the IC device(s) 218. As another example, a plating tool 112 may be used to deposit metal structures and/or layers of the IC device(s) 218.

In FIG. 4B, a deposition tool 102 may be used to deposit the dielectric layer 220 over and/or on the substrate 216. The deposition tool 102 may be used to deposit the dielectric layer 220 in a PVD operation, an ALD operation, a CVD operation, an epitaxy operation, an oxidation operation, another type of deposition operation described in connection with FIG. 1, and/or another suitable deposition operation. In some implementations, the planarization tool 110 may be used to planarize the dielectric layer 220 after the dielectric layer 220 is deposited.

As shown in FIG. 4C, a deposition tool 102 may be used be used to deposit alternating layers of ESLs 226 and ILDs 224 of the interconnect region 222 of the semiconductor die 200. The deposition tool 102 may be used to deposit the ESLs 226 and the ILDs 224 in a PVD operation, an ALD operation, a CVD operation, an epitaxy operation, an oxidation operation, another type of deposition operation described in connection with FIG. 1, and/or another suitable deposition operation. In some implementations, a planarization tool 110 may be used to planarize the dielectric layer ESLs 226and/or the ILDs 224 after the ESLs 226 and/or the ILDs 224 are deposited.

A deposition tool 102, an exposure tool 104, a developer tool 106, an etch tool 108, a planarization tool 110, and/or a plating tool 112 may be used to perform various operations to form the metallization layers 228 in the active device region 204 of the semiconductor die 200. The metallization layers 228 may be electrically coupled with the IC device(s) 218.

As indicated above, FIGS. 4A-4C are provided as an example. Other examples may differ from what is described with regard to FIGS. 4A-4C.

FIGS. 5A-5H are diagrams of example semiconductor processing operations 500 related to forming a semiconductor die described herein (e.g., the semiconductor die 200). The semiconductor processing operations 500 include forming, using, and removing a temporary conductive structure (e.g., the temporary conductive structure 212) within a region of the semiconductor die (e.g., the interconnect pad region 232). One or more of the semiconductor processing tools 102-114 and/or the wafer/die transport tool 116 may be used to perform one or more of the semiconductor processing operations 500 described in connection with FIGS. 5A-5H. In some implementations, one or more of the semiconductor processing operations described in connection with FIGS. 5A-5H may be performed using another semiconductor processing tool.

Turning to FIG. 5A, and as part of the interconnect pad region 232 and/or the overlay region 214, the top dielectric layer 230 is formed. A deposition tool 102 may be used to form the top dielectric layer 230 over a region of a semiconductor die (e.g., the interconnect region 222 of the semiconductor die 200). The deposition tool 102 may be used to deposit the top dielectric layer 230 in a PVD operation, an ALD operation, a CVD operation, an epitaxy operation, an oxidation operation, another type of deposition operation described in connection with FIG. 1, and/or another suitable deposition operation. In some implementations, a planarization tool 110 may be used to planarize the top dielectric layer 230 after the top dielectric layer 230 is deposited.

A deposition tool 102, an exposure tool 104, a developer tool 106, an etch tool 108, a planarization tool 110, and/or a plating tool 112 may be used to perform various operations to form portions of the metallization layers 228. Within the top dielectric layer 230, the metallization layers 228 may correspond to vertical access interconnect structures (vias), among other examples.

As shown in FIG. 5B, a conductive layer 502, a conductive layer 504, and an anti-reflective coating (ARC) layer 506 are formed on and/or over the top dielectric layer 230 and the metallization layers 228. The conductive layer 502 may include a tantalum nitride (TaN) material, among other examples. The conductive layer 504 may include an aluminum (Al) material, among other examples. The ARC layer 506 may include an aluminum oxide (AlOₓ) material, among other examples.

A deposition tool 102 and/or a plating tool 112 may be used to deposit the conductive layer 502, the conductive layer 504, and/or the ARC layer 506 in a CVD operation, a PVD operation, an ALD operation, an electroplating operation, another deposition operation described above in connection with FIG. 1, and/or another suitable deposition operation. In some implementations, a seed layer is first deposited, and the conductive layer 504 is deposited on the seed layer. In some implementations, a planarization tool 110 may be used to planarize the conductive layer 502, the conductive layer 504, and/or the ARC layer 506 after the conductive layer 502, the conductive layer 504, and/or the ARC layer 506 is deposited.

In some implementations, a thickness D2 of the ARC layer 506 is included in a range of approximately 60 angstroms (Å) to approximately 100 Å. Selecting a thickness D2 that is less than approximately 60 Å may have a detrimental effect on a subsequent patterning operation that exposes a photoresist layer on the ARC layer 506 (e.g., the ARC layer 506 may be ineffective in reducing a reflection of light from the conductive layer 504 during exposure by an exposure tool 104). Selecting a thickness D2 that is between approximately 60 Å and 100 Å may enable the ARC layer 506 to be effective in reducing the reflection of light. Additionally, or alternatively, selecting a thickness D2 that is between approximately 60 Å and 100 Å may satisfy a resistivity threshold associated with a temporary conductive structure (e.g., the temporary conductive structure 212) including the ARC layer 506 such that the temporary conductive structure may be used as part of a testing operation that tests underlying IC devices (e.g., the IC device(s) 218). Selecting a thickness D2 that is greater than approximately 100 Å may fail to satisfy the resistivity threshold and cause the temporary conductive structure to not be useable for the testing operation. However, other values and ranges for the thickness D2 are within the scope of the present disclosure.

As shown in FIG. 5C, a mask structure 508 is formed on and/or over the ARC layer 506. As part of forming the mask structure 508, a deposition tool 102 may be used to form a photoresist layer (e.g., a layer of photoresist material) on the ARC layer 506. An exposure tool 104 may be used to expose the photoresist layer to a radiation source to pattern the photoresist layer. A developer tool 106 may be used to develop and remove portions of the photoresist layer to form the mask structure 508 from the photoresist layer.

In some implementations, other techniques (e.g., a sequence of deposition, patterning, and etching operations) may be used to form the mask structure 508 using a material other than a photoresist material. In such cases, the mask structure 508 may be referred to as a hard mask structure.

As shown in FIG. 5D, and based on a combination of materials used to form the ARC layer 506, the conductive layer 504, and the conductive layer 502 (e.g., aluminum oxide (AlOₓ) on aluminum (Al) on tantalum nitride (TaN)) a single etching operation forms the temporary conductive structure 212 and removes a portion of the top dielectric layer 230 (e.g., forms a recess in the top dielectric layer 230) to expose surface(s) 510. In contrast to a using a different combination of materials that may necessitate two or more etching operations (e.g., silicon oxynitride (SiON) on aluminum (Al) on tantalum nitride (TaN)), a depth of the surface(s) 510 is reduced. In some implementations, reducing the depth of the surface(s) 510 reduces a step height and/or a difference in step heights within the interconnect pad region 232 (e.g., the step height D1a and/or the difference between step height D1a and D1b as described in connection with FIG. 3B).

An etch tool 108 may be used to etch of the ARC layer 506, the conductive layer 504, and the conductive layer 502 based on the mask structure 508 (e.g., remove unmasked portions of the ARC layer 506, the conductive layer 504, and the conductive layer 502). In some implementations, the etch tool 108 uses an etchant that includes a chlorine (Cl) chemistry. In some implementations, and after the etching operation, a photoresist removal tool may be used to remove the mask structure 508 (e.g., using a chemical stripper, plasma ashing, and/or another technique).

As shown in FIG. 5E, the IC device(s) 218 are tested. A wafer testing tool 114 may be used to test the IC device(s) 218. In some implementations, and as shown in FIG. 5E, the wafer testing tool 114 may make electrical contact with the test pad 210 (e.g., make electrical contact with the test pad 210 using a needle or probe), where ethe test pad 210 is electrically coupled with the temporary conductive structure 212 to test the IC device(s) 218. In some implementations, the ARC layer 506 may be shared with the test pad 210 (e.g., the wafer testing tool 114 may make electrical contact by probing a portion of the ARC layer 506 that is part of the test pad 210).

As shown in FIG. 5F, the temporary conductive structure 212 is removed. As an example, a planarization tool 110 may be used to remove the temporary conductive structure 212 using a CMP process or another suitable planarization process. As another example, an etch tool 108 may be used to remove the temporary conductive structure 212. In such a case, a deposition tool 102 may be used to form the photoresist layer on and/or over the interconnect pad region 232. An exposure tool 104 may be used to expose the photoresist layer to a radiation source to pattern the photoresist layer. A developer tool 106 may be used to develop and remove portions of the photoresist layer to expose the temporary conductive structure 212. An etch tool 108 may be used to remove the temporary conductive structure 212. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique).

As shown in FIG. 5G, a conductive layer 512 is formed on and/or over the top dielectric layer 230 and/or the metallization layers 228. The conductive layer 512 may include aluminum (Al), copper, (Cu) aluminum copper (AlCu), tungsten (W), cobalt (Co), ruthenium (Ru), titanium (Ti), gold (Au) or another suitable conductive material. A deposition tool 102 and/or a plating tool 112 may be used to deposit the conductive layer 512 in a CVD operation, a PVD operation, an ALD operation, an electroplating operation, another deposition operation described above in connection with FIG. 1, and/or another suitable deposition operation. In some implementations, a seed layer is first deposited, and the conductive layer 512 is deposited on the seed layer. In some implementations, the planarization tool 110 may be used to planarize the conductive layer 512 after the conductive layer 512 is deposited.

Further, and as shown in FIG. 5G, mask structures 514 are formed on and/or over the conductive layer 512. As part of forming the mask structures 514, a deposition tool 102 may be used to form a photoresist layer (e.g., a layer of photoresist material) on the conductive layer 512. An exposure tool 104 may be used to expose the photoresist layer to a radiation source to pattern the photoresist layer. A developer tool 106 may be used to develop and remove portions of the photoresist layer to form the mask structures 514 from the photoresist layer.

In some implementations, other techniques (e.g., a sequence of deposition, patterning, and etching operations) may be used to form the mask structures 514 using a material other than a photoresist material. In such cases, the mask structures 514 may be referred to as hard mask structures.

As shown in FIG. 5H, the interconnect pad structures 208a and 208b are formed from the conductive layer 512. An etch tool 108 may be used to etch the conductive layer 512 and/or the top dielectric layer 230 based on the mask structures 514 (e.g., remove unmasked portions of the conductive layer 512 and the dielectric layer 320). In such a case, the etch tool 108 may use a plasma etch operation, a wet chemical etch operation, and/or another type of etch operation. In some implementations, and after the etching operation, a photoresist removal tool may be used to remove the mask structures 514 (e.g., using a chemical stripper, plasma ashing, and/or another technique).

Furthermore, and based on the single etching operation described in connection with FIG. 5D, a difference between the step height D1a and the step height D1b is reduced (e.g., reduced relative to another series of semiconductor processing operations using multiple etching operations to form the temporary conductive structure 212). For example, and in some implementations, the difference between the step height D1a and D1b may be reduced to be less than approximately 80 nanometers to enable a pick-and-place tool (e.g., the wafer/die transport tool 116) to repeatably pick-and-place a semiconductor die (e.g., the semiconductor die 200). However, other values and ranges for the difference between the step height D1a and the step height D1b are within the scope of the present disclosure.

In this way, a magnitude and a uniformity of a contact force between a pick-and-place tool and the interconnect pad structures 208a and 208b is maintained to enable a repeatable and reliable pick-and-place operation (e.g., the pick-and-place operation as described in connection with FIGS. 3A and 3B). This increases the productivity of the pick-and-place tool and/or reduces the likelihood of damage to a semiconductor die (e.g., the semiconductor die 200) including the interconnect pad structures 208a and 208b.

As indicated above, FIGS. 5A-5H are provided as an example. Other examples may differ from what is described with regard to FIGS. 5A-5H.

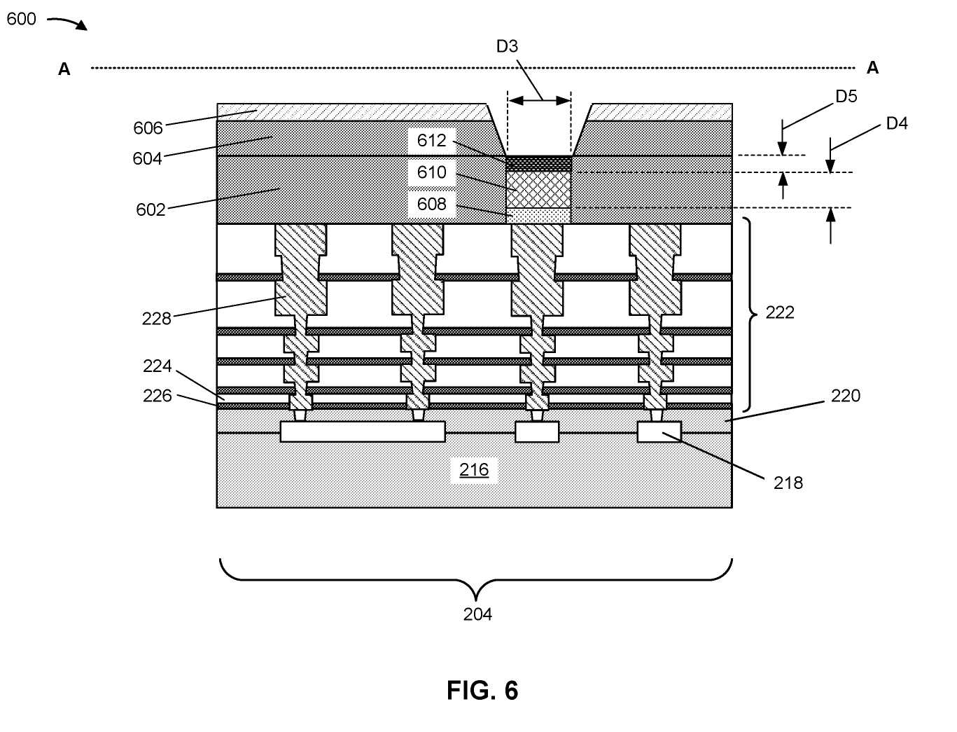

FIG. 6 is a diagram of an example semiconductor die 600 described herein. Using semiconductor processing operations similar to those described in connection with FIGS. 5A-5H, one or more of the semiconductor processing tools 102-114 and/or the wafer/die transport tool 116 may be used to form the semiconductor die 600. Furthermore, an example of the semiconductor die 600 includes a logic die.

As shown in FIG. 6, the semiconductor die 600 includes a dielectric layer 602 (e.g., a first passivation layer including silicon dioxide (SiO₂) or aluminum oxide (Al₂0₃)) a dielectric layer 604 (e.g., a second passivation layer including silicon dioxide (SiO₂) or aluminum oxide (Al₂0₃)) and a dielectric layer 606 (e.g., a capping layer including silicon nitride (SiN)) over the interconnect region 222.

The semiconductor die 600 further includes a layer stack over the metallization layer 228. The layer stack includes a conductive layer 608 (e.g., a tantalum nitride layer), a conductive layer 610 (e.g., an aluminum-copper alloy layer) on the conductive layer 608, and an ARC layer 612 (e.g., an aluminum oxide layer) on the conductive layer 610. As shown in FIG. 6, the conductive layer 608 is between the conductive layer 610 and the metallization layer 228. In some implementations the layer stack is used as part of a pad structure for the semiconductor die 600 (e.g., for interfacing with a bump or another interconnect structure).

As shown in FIG. 6, the conductive layer 610 and the ARC layer 612 have a same approximate width D3. Furthermore, a thickness D4 of the conductive layer 610 is greater than a thickness D5 of the ARC layer 612. As such, an aspect ratio D3:D4 of conductive layer 610 is less than an aspect ratio D3:D5 of the ARC layer 612.

In some implementations, the ARC layer 612 reduces a likelihood of defects within the layer stack, such as pitting due to galvanic effects on the surface of conductive layer 610. Additionally, or alternatively and in some implementations, the ARC layer 612 reduces a likelihood of F-corrosion effects on a surface of the conductive layer 610.

As described in connection with FIG. 6, some implementations described herein provide a semiconductor die (e.g., the semiconductor die 600). The semiconductor die includes a metallization layer (e.g., the metallization layer 228). The semiconductor die includes a layer stack over the metallization layer. The layer stack includes an aluminum-copper alloy layer (e.g., the conductive layer 610) and an aluminum oxide layer (e.g., the ARC layer 612) on the aluminum-copper alloy layer, where an aspect ratio of the aluminum-copper alloy layer (D3:D5) is less than an aspect ratio of the aluminum oxide layer (D4:D5).

As indicated above, FIG. 6 is provided as an example. Other examples may differ from what is described with regard to FIG. 6.

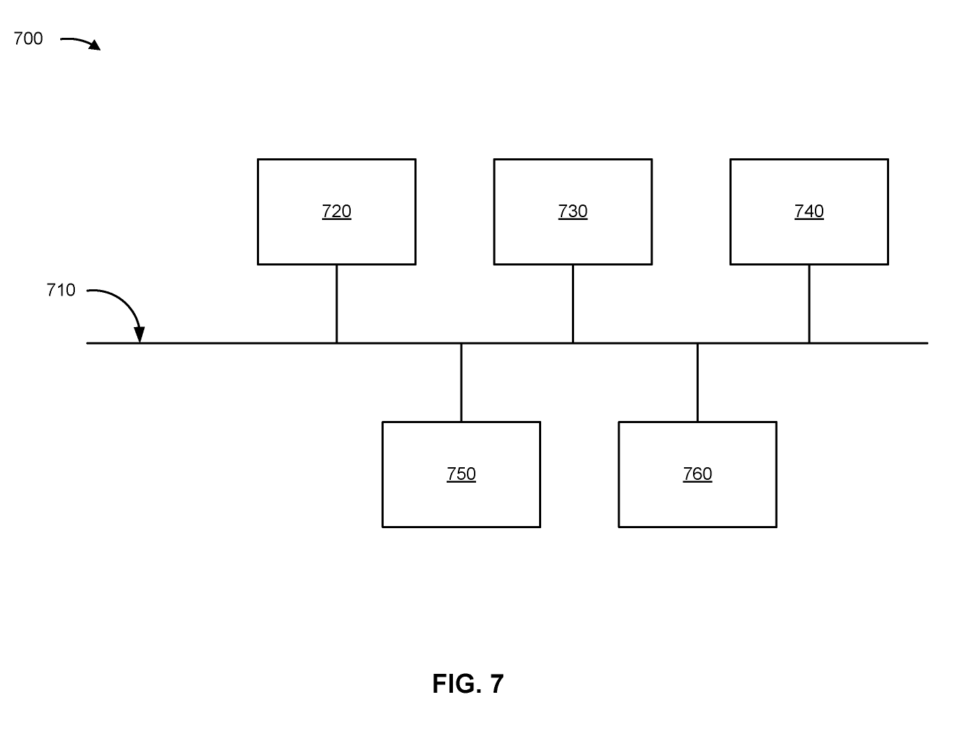

FIG. 7 is a diagram of example components of a device 700 described herein. In some implementations, one or more of the semiconductor processing tools 102-b and/or the wafer/die transport tool 116 may include one or more devices 700 and/or one or more components of the device 700. As shown in FIG. 7, the device 700 may include a bus 710, a processor 720, a memory 730, an input component 740, an output component 750, and/or a communication component 760.

The bus 710 may include one or more components that enable wired and/or wireless communication among the components of the device 700. The bus 710 may couple together two or more components of FIG. 7, such as via operative coupling, communicative coupling, electronic coupling, and/or electric coupling. For example, the bus 710 may include an electrical connection (e.g., a wire, a trace, and/or a lead) and/or a wireless bus. The processor 720 may include a central processing unit, a graphics processing unit, a microprocessor, a controller, a microcontroller, a digital signal processor, a field-programmable gate array, an application-specific integrated circuit, and/or another type of processing component. The processor 720 may be implemented in hardware, firmware, or a combination of hardware and software. In some implementations, the processor 720 may include one or more processors capable of being programmed to perform one or more operations or processes described elsewhere herein.

The memory 730 may include volatile and/or nonvolatile memory. For example, the memory 730 may include random access memory (RAM), read only memory (ROM), a hard disk drive, and/or another type of memory (e.g., a flash memory, a magnetic memory, and/or an optical memory). The memory 730 may include internal memory (e.g., RAM, ROM, or a hard disk drive) and/or removable memory (e.g., removable via a universal serial bus connection). The memory 730 may be a non-transitory computer-readable medium. The memory 730 may store information, one or more instructions, and/or software (e.g., one or more software applications) related to the operation of the device 700. In some implementations, the memory 730 may include one or more memories that are coupled (e.g., communicatively coupled) to one or more processors (e.g., processor 720), such as via the bus 710. Communicative coupling between a processor 720 and a memory 730 may enable the processor 720 to read and/or process information stored in the memory 730 and/or to store information in the memory 730.

The input component 740 may enable the device 700 to receive input, such as user input and/or sensed input. For example, the input component 740 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 750 may enable the device 700 to provide output, such as via a display, a speaker, and/or a light-emitting diode. The communication component 760 may enable the device 700 to communicate with other devices via a wired connection and/or a wireless connection. For example, the communication component 760 may include a receiver, a transmitter, a transceiver, a modem, a network interface card, and/or an antenna.

The device 700 may perform one or more operations or processes described herein. For example, a non-transitory computer-readable medium (e.g., memory 730) may store a set of instructions (e.g., one or more instructions or code) for execution by the processor 720. The processor 720 may execute the set of instructions to perform one or more operations or processes described herein. In some implementations, execution of the set of instructions, by one or more processors 720, causes the one or more processors 720 and/or the device 700 to perform one or more operations or processes described herein. In some implementations, hardwired circuitry may be used instead of or in combination with the instructions to perform one or more operations or processes described herein. Additionally, or alternatively, the processor 720 may be configured to perform one or more operations or processes described herein. Thus, implementations described herein are not limited to any specific combination of hardware circuitry and software.

The number and arrangement of components shown in FIG. 7 are provided as an example. The device 700 may include additional components, fewer components, different components, or differently arranged components than those shown in FIG. 7. Additionally, or alternatively, a set of components (e.g., one or more components) of the device 700 may perform one or more functions described as being performed by another set of components of the device 700.

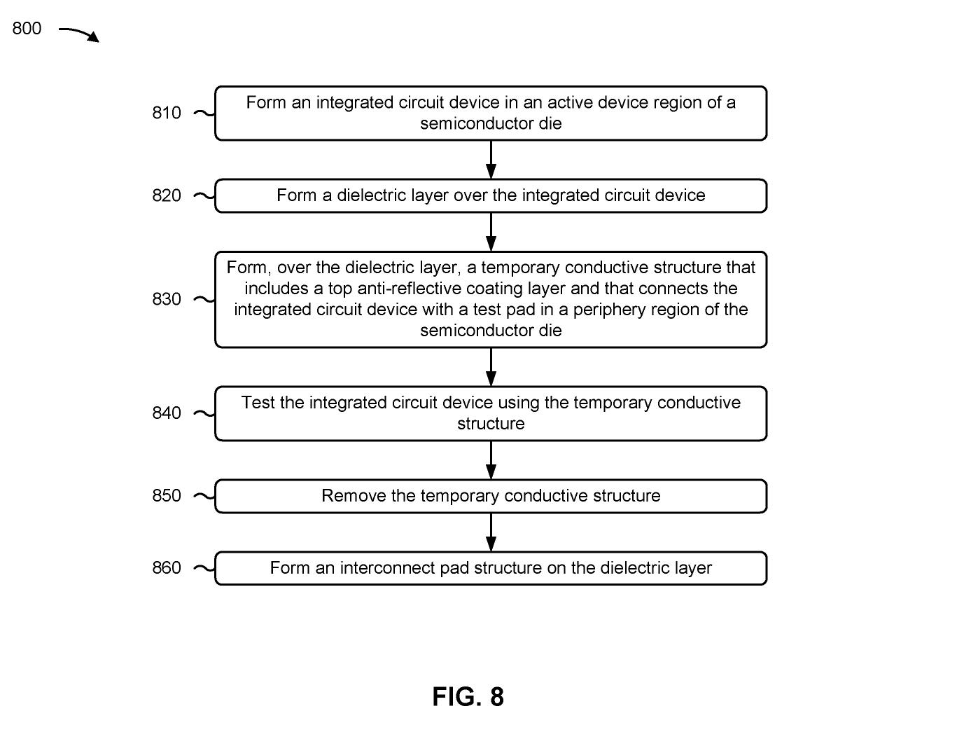

FIG. 8 is a flowchart of an example process 800 associated with forming a semiconductor die described herein. In some implementations, one or more process blocks of FIG. 8 are performed using one or more semiconductor processing tools (e.g., one or more of the semiconductor processing tools 102-114). Additionally, or alternatively, one or more process blocks of FIG. 8 may be performed using one or more components of device 700, such as processor 720, memory 730, input component 740, output component 750, and/or communication component 760.

As shown in FIG. 8, process 800 may include forming an IC device in an active device region of a semiconductor die (block 810). For example, one or more of the semiconductor processing tools 102-114 may be used to form an IC device (e.g., the IC device(s) 218) in an active device region (e.g., the active device region 204) of a semiconductor die (e.g., the semiconductor die 200), as described herein.

As further shown in FIG. 8, process 800 may include forming a dielectric layer over the IC device (block 820). For example, one or more of the semiconductor processing tools 102-114 may be used to form a dielectric layer (e.g., the top dielectric layer 230) over the IC device, as described herein.

As further shown in FIG. 8, process 800 may include forming, over the dielectric layer, a temporary conductive structure that includes a top anti-reflective coating layer and that connects the IC device with a test pad in a periphery region of the semiconductor die (block 830). For example, one or more of the semiconductor processing tools 102-114 may be used to form, over the dielectric layer, a temporary conductive structure (e.g., the temporary conductive structure 212) that includes a top anti-reflective coating layer(e.g., the anti-reflective coating layer 506) and that connects the IC device with a test pad (e.g., the test pad 210) in a periphery region (e.g., the periphery region 206) of the semiconductor die, as described herein. In some implementations, forming the temporary conductive structure includes using a single etch operation to remove portions of the top anti-reflective coating layer and portions of one or more conductive layers (e.g., the conductive layers 502 and 504) between the top anti-reflective coating layer and the dielectric layer.

As further shown in FIG. 8, process 800 may include testing the IC device using the temporary conductive structure (block 840). For example, one or more of the semiconductor processing tools 102-114 may be used to test the IC device using the temporary conductive structure, as described herein.

As further shown in FIG. 8, process 800 may include removing the temporary conductive structure (block 850). For example, one or more of the semiconductor processing tools 102-114 may be used to remove the temporary conductive structure, as described herein.

As further shown in FIG. 8, process 800 may include forming an interconnect pad structure on the dielectric layer (block 860). For example, one or more of the semiconductor processing tools 102-114 may be used to form an interconnect pad structure (e.g., the interconnect pad structure 208a) on the dielectric layer, as described herein.

Process 800 may include additional implementations, such as any single implementation or any combination of implementations described below and/or in connection with one or more other processes described elsewhere herein.

In a first implementation, forming the temporary conductive structure includes depositing an aluminum oxide layer to form the top anti-reflective layer.

In a second implementation, alone or in combination with the first implementation, forming the temporary conductive structure includes depositing a tantalum nitride layer (e.g., the conductive layer 502), depositing an aluminum layer (e.g., the conductive layer 504) on the tantalum nitride layer, and depositing an aluminum oxide layer (e.g., the anti-reflective coating layer 506) on the aluminum layer.

In a third implementation, alone or in combination with one or more of the first and second implementations, forming the temporary conductive structure includes forming a mask structure (e.g., the mask structure 508) on the aluminum oxide layer, and removing unmasked portions of the aluminum oxide layer, the aluminum layer, and the tantalum nitride layer using the single etch operation.

In a fourth implementation, alone or in combination with one or more of the first through third implementations, removing the unmasked portions of the aluminum oxide layer, the aluminum layer, and the tantalum nitride layer using the single etch operation forms a recess (e.g., a recess to expose the surface 510) adjacent to the temporary conductive structure in the dielectric layer below the temporary conductive structure.

In a fifth implementation, alone or in combination with one or more of the first through fourth implementations, process 800 includes removing the semiconductor die from a carrier (e.g., the carrier 302) holding the semiconductor die, where a likelihood of a degradation in a pick force (e.g., the pick force 304) used to remove the semiconductor die is reduced based on a step height (e.g., the step height D1a) from a surface of the recess to a top surface of the interconnect pad structure.

In a sixth implementation, alone or in combination with one or more of the first through fifth implementations, the step height is reduced relative to another step height associated with another recess formed using multiple etch operations.

In a seventh implementation, alone or in combination with one or more of the first through sixth implementations, testing the IC device using the temporary conductive structure includes probing the test pad.

In an eighth implementation, alone or in combination with one or more of the first through seventh implementations, the top anti-reflective coating layer is shared with the test pad, and probing the test pad includes probing the top anti-reflective layer.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

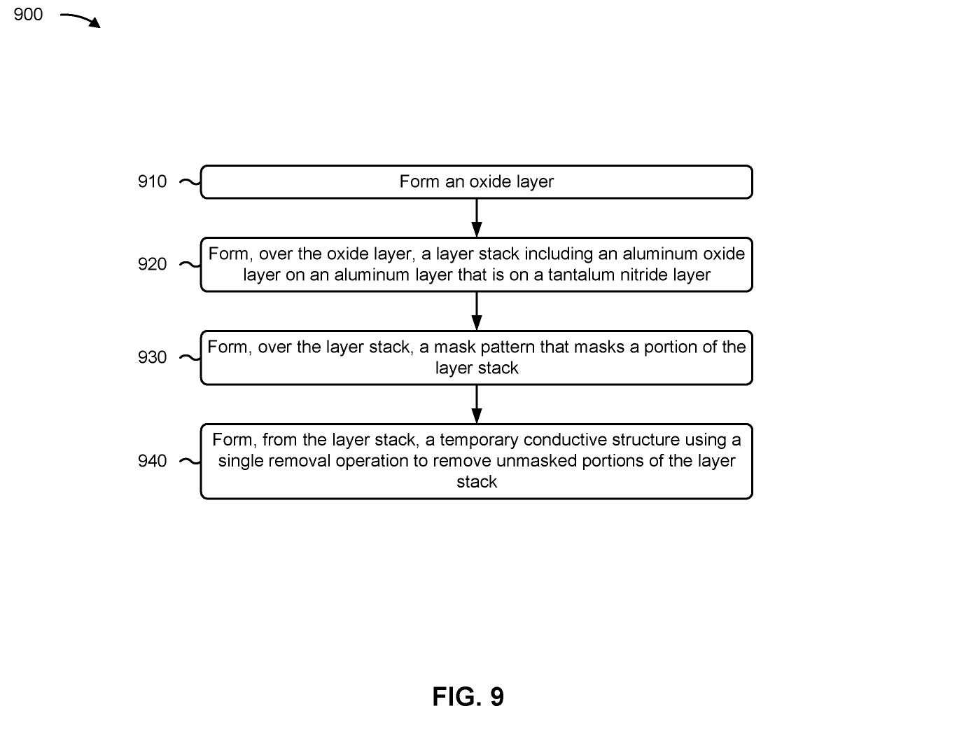

FIG. 9 is a flowchart of an example process 900 associated with forming a semiconductor die described herein. In some implementations, one or more process blocks of FIG. 9 are performed using one or more semiconductor processing tools (e.g., one or more of the semiconductor processing tools 102-114). Additionally, or alternatively, one or more process blocks of FIG. 9 may be performed using one or more components of device 700, such as processor 720, memory 730, input component 740, output component 750, and/or communication component 760.

As shown in FIG. 9, process 900 may include forming an oxide layer (block 910). For example, one or more of the semiconductor processing tools 102-114 may be used to form an oxide layer (e.g., the top dielectric layer 230), as described herein.

As further shown in FIG. 9, process 900 may include forming, over the oxide layer, a layer stack including an aluminum oxide layer on an aluminum layer that is on a tantalum nitride layer (block 920). For example, one or more of the semiconductor processing tools 102-114 may be used to form, over the oxide layer, a layer stack including an aluminum oxide layer (e.g., the anti-reflective coating layer 506) on an aluminum layer (e.g., the conductive layer 504) that is on a tantalum nitride layer (e.g., the conductive layer 502), as described herein.

As further shown in FIG. 9, process 900 may include forming, over the layer stack, a mask pattern that masks a portion of the layer stack (block 930). For example, one or more of the semiconductor processing tools 102-114 may be used to form, over the layer stack, a mask pattern (e.g., the mask structure 508) that masks a portion of the layer stack, as described herein.

As further shown in FIG. 9, process 900 may include forming, from the layer stack, a temporary conductive structure using a single removal operation to remove unmasked portions of the layer stack (block 940). For example, one or more of the semiconductor processing tools 102-114 may be used to form, from the layer stack, a temporary conductive structure (e.g., the temporary conductive structure 212) using a single removal operation to remove unmasked. portions of the layer stack, as described herein.

Process 900 may include additional implementations, such as any single implementation or any combination of implementations described below and/or in connection with one or more other processes described elsewhere herein.

In a first implementation, for the aluminum oxide layer includes forming the aluminum oxide layer to have a thickness (e.g., the thickness D2) that is included in a range of approximately 60 Å to approximately 100 Å.

In a second implementation, alone or in combination with the first implementation, forming the temporary conductive structure includes forming a portion of the temporary conductive structure over an overlay region (e.g., the overlay region 214) used for formation of a micro LED bump interconnect structure (e.g., the interconnect pad structure 208a) and further including testing micro LED circuitry (e.g., the IC device(s) 218) using the temporary conductive structure, removing the temporary conductive structure, and forming the micro LED bump interconnect structure in the overlay region.

In a third implementation, alone or in combination with one or more of the first and second implementations, forming the mask pattern includes forming the mask pattern from a photoresist material on the aluminum oxide layer.

In a fourth implementation, alone or in combination with one or more of the first through third implementations, the aluminum oxide layer inhibits a reflection of light from the layer stack during a photolithography operation that exposes the photoresist material.

In a fifth implementation, alone or in combination with one or more of the first through fourth implementations, forming the mask pattern includes forming the mask pattern from a hard mask layer on the aluminum oxide layer.

In a sixth implementation, alone or in combination with one or more of the first through fifth implementations, using the single removal operation includes using a single etch operation.

In a seventh implementation, alone or in combination with one or more of the first through sixth implementations, using the single etch operation includes using an etchant including chlorine.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

Some implementations herein include a semiconductor die and methods of formation. The semiconductor die includes an array of interconnect pad structures, including interconnect pad structures having surfaces located within an overlay region of an active device area of the semiconductor die. As part of manufacturing the semiconductor die, temporary conductive structures are formed across the overlay region to support a WAT testing and/or CP testing process. Forming the temporary conductive structures includes using an anti-reflective coating layer having a composition that enables the temporary conductive structures to be formed using a single etch cycle. Relative to other semiconductor dies manufactured using temporary conductive structures formed using an anti-reflective coating layer having another composition (and that may require multiple etch cycles), the semiconductor die includes a reduced difference in step heights between interconnect pad structures in the overlay region and other regions of the active device area.

In this way, a magnitude and a uniformity of a contact force between a pick-and-place tool and the semiconductor die is maintained to enable a repeatable and reliable pick-and-place operation. This increases the productivity of the pick-and-place tool (the pick-and-place tool can spend less time attempting to securely pick up and move the semiconductor die, thereby processing a greater quantity of semiconductor dies) and/or reduces the likelihood of damage to the semiconductor die, among other examples.

As described in greater detail above, some implementations described herein provide a method. The method includes forming an IC device in an active device region of a semiconductor die. The method includes forming a dielectric layer over the IC device. The method includes forming, over the dielectric layer, a temporary conductive structure that includes a top anti-reflective coating layer and that connects the IC device with a test pad in a periphery region of the semiconductor die, where forming the temporary conductive structure includes using a single etch operation to remove portions of the top anti-reflective coating layer and portions of one or more conductive layers between the top anti-reflective coating layer and the dielectric layer. The method includes testing the IC device using the temporary conductive structure. The method includes removing the temporary conductive structure. The method includes forming an interconnect pad structure on the dielectric layer.

As described in greater detail above, some implementations described herein provide a method. The method includes forming an oxide layer. The method includes forming, over the oxide layer, a layer stack including an aluminum oxide layer on an aluminum layer that is on a tantalum nitride layer. The method includes forming, over the layer stack, a mask pattern that masks a portion of the layer stack. The method includes forming, from the layer stack, a temporary conductive structure using a single removal operation to remove unmasked portions of the layer stack.

As described in greater detail above, some implementations described herein provide a semiconductor die. The semiconductor die includes a metallization layer. The semiconductor die includes a layer stack over the metallization layer. The layer stack includes an aluminum-copper alloy layer and an aluminum oxide layer on the aluminum-copper alloy layer, where an aspect ratio of the aluminum-copper alloy layer is less than an aspect ratio of the aluminum oxide layer.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor die, comprising:
a metallization layer; and
a layer stack over the metallization layer comprising:
an aluminum-copper alloy layer; and
an aluminum oxide layer on the aluminum-copper alloy layer,
wherein an aspect ratio of the aluminum-copper alloy layer is less than an aspect ratio of the aluminum oxide layer.

2. The semiconductor die of claim 1, wherein the layer stack further comprises:
a tantalum nitride layer,
wherein the tantalum nitride layer is between the aluminum-copper alloy layer and the metallization layer.

3. The semiconductor die of claim 1, wherein the layer stack is included in a pad structure for a bump of the semiconductor die.

4. The semiconductor die of claim 1, wherein the aluminum-copper alloy layer and the aluminum oxide layer have approximately a same width.

5. The semiconductor die of claim 1, wherein a thickness of the aluminum-copper alloy layer is greater than a thickness of the aluminum oxide layer.

6. The semiconductor die of claim 1, further comprising a dielectric layer over the metallization layer, wherein the layer stack is positioned on the dielectric layer.

7. The semiconductor die of claim 6, wherein the dielectric layer is a passivation layer comprising silicon dioxide or aluminum oxide.

8. A semiconductor die, comprising:
a metallization layer;
a layer stack over the metallization layer comprising:
a tantalum nitride layer;
an aluminum-copper alloy layer on the tantalum nitride layer; and
an aluminum oxide layer on the aluminum-copper alloy layer,
wherein a thickness of the aluminum-copper alloy layer is greater than a thickness of the aluminum oxide layer; and
a dielectric stack over the metallization layer and adjacent to the layer stack, the dielectric stack comprising:
a first passivation layer;
a second passivation layer over the first passivation layer; and
a capping layer over the second passivation layer.

9. The semiconductor die of claim 8, wherein the first passivation layer comprises silicon dioxide or aluminum oxide.

10. The semiconductor die of claim 8, wherein the second passivation layer comprises silicon dioxide or aluminum oxide.

11. The semiconductor die of claim 8, wherein the capping layer comprises silicon nitride.

12. The semiconductor die of claim 8, wherein the aluminum-copper alloy layer and the aluminum oxide layer have a same approximate width.

13. The semiconductor die of claim 8, wherein an aspect ratio of the aluminum-copper alloy layer is less than an aspect ratio of the aluminum oxide layer.

14. The semiconductor die of claim 8, wherein the layer stack is a pad structure for interfacing with a bump.

15. A semiconductor die, comprising:
a metallization layer; and
a layer stack over the metallization layer, wherein the layer stack forms a pad structure for interfacing with a bump, the layer stack comprising:
a first conductive layer comprising tantalum nitride;
a second conductive layer on the first conductive layer, the second conductive layer comprising an aluminum-copper alloy; and
an anti-reflective coating layer on the second conductive layer, the anti-reflective coating layer comprising aluminum oxide;
wherein the second conductive layer and the anti-reflective coating layer have a same approximate width, and an aspect ratio of the second conductive layer is less than an aspect ratio of the anti-reflective coating layer.

16. The semiconductor die of claim 15, wherein a thickness of the second conductive layer is greater than a thickness of the anti-reflective coating layer.

17. The semiconductor die of claim 15, wherein the first conductive layer is between the second conductive layer and the metallization layer.

18. The semiconductor die of claim 15, further comprising:
a first passivation layer,
a second passivation layer over the first passivation layer, and
a capping layer over the second passivation layer,
wherein the first passivation layer, the second passivation layer, and the capping layer are adjacent to the layer stack.

19. The semiconductor die of claim 18, wherein the capping layer comprises silicon nitride and is positioned over an interconnect region that includes the metallization layer.

20. The semiconductor die of claim 15, wherein the anti-reflective coating layer is configured to reduce galvanic pitting on a surface of the second conductive layer.
